(19) United States
(12) Patent Application Publication
(10) Pub. No.: US 2019/0341510 A1
(43) Pub. Date: Nov. 7, 2019

(54) CHALCOGENIDE THIN FILM SOLAR CELL HAVING TRANSPARENT BACK ELECTRODE

(71) Applicant: KOREA INSTITUTE OF SCIENCE AND TECHNOLOGY, Seoul (KR)

(72) Inventors: Won Mok KIM, Seoul (KR); Jeung Hyun JEONG, Seoul (KR); Jong Keuk PARK, Seoul (KR); Sung Bin CHOI, Seoul (KR)

(21) Appl. No.: 16/186,588

(22) Filed: Nov. 12, 2018

(30) Foreign Application Priority Data
May 4, 2018 (KR) 10-2018-0051808

(51) Int. Cl. H01L 31/0224; H01L 31/0445; H01L 31/032

(52) U.S. Cl. CPC H01L 31/022466; H01L 31/022483; H01L 31/0322; H01L 31/0445

(57) ABSTRACT

Provided is a chalcogenide thin film solar cell having a transparent back electrode, including a transparent substrate, a photoactive layer including an S, Se-based chalcogenide material, and a back electrode disposed between the transparent substrate and the photoactive layer and including a transparent conductive oxide containing titanium (Ti).

### BACKGROUND

The present disclosure relates to a thin film solar cell using an S, Se-based chalcogenide compound semiconductor represented by CGIS as a photoactive layer, and more particularly, to a thin film solar cell using a transparent conductive oxide thin film as a lower electrode.

Solar cells are classified into various categories depending on which material is used as a light absorbing layer. Although solar cells mainly using silicon as a light absorbing layer are most representative, recently, researches on a chalcogenide solar cell using a chalcogenide material, which has high efficiency, as a light absorbing layer have been in the spotlight.

A thin film solar cell made of an S, Se-based chalcogenide compound semiconductor represented by Cu(In₁₋ₓ, Gaₓ)(Se,S)₂ (CIGS) is expected to be a next-generation, low-cost, highly-efficient solar cell since it is possible to achieve high photoelectric conversion efficiency (achieving CIGS photoelectric conversion efficiency of 22.6%—Germany ZSW) due to high light absorption and excellent semiconductor properties thereof. CIGS thin films can be grown on metal substrates or polymer substrates as well as on rigid glass substrates, and thus may be developed into flexible solar cells. In addition, CIGS thin film solar cells can freely change bandgap by changing the ratio of Ga/(In+Ga) or the ratio of Se/(Se+S), and thus, it is advantageous in designing a material for a light absorption layer corresponding to optical spectrum of sunlight or an external light source. Specifically, a Se-based solar cell may change bandgap from 1.0 to 1.7e V according to the ratio of In/(In+Ga). CIGS thin-film solar cells currently shows the highest photoelectric conversion efficiency performance in a range of 1.1-1.2 eV bandgap, but a higher performance implementation may be achieved from a composition corresponding to 1.4-1.5 eV bandgap, in which it is possible to achieve theoretically the highest photoelectric conversion efficiency. In addition, it is also possible to employ a tandem solar cell utilizing a 1.7 eV bandgap material suitable for an upper cell of a tandem solar cell having two junctions.

Commonly, methods for manufacturing thin film solar cells using an S, Se-based chalcogenide compound semiconductor represented by CGIS as a photoactive layer are largely classified into two types.

The first type is a type in which Cu, In, and Ga, which are constituent metal elements, are first deposited in a metal state on an electrode layer, and then subjected to heat treatment in a gaseous atmosphere containing selenium or sulfur to prepare an S, Se-based chalcogenide compound having a desired composition. In some cases, rather than depositing Cu, In, and Ga in a pure metal state, some elements are deposited in the form of selenide or sulfide, and then subjected to heat treatment in a gaseous atmosphere containing selenium or sulfur. As a method for preparing a metal layer or a portion thereof in the form of selenide or sulfide before the heat treatment, an evaporation method or a sputtering method may be used. As described above, in the first type, a metal layer composed of constituent metal elements or a layer in which a portion thereof is selenide or sulfide is formed first, and then the heat treatment is performed. Thus, such manufacturing method is commonly referred to as a two-step process.

The second type uses an evaporation method in which while selenium (Se) is being evaporated, Cu, In, and Ga, which are metal components, are evaporated to prepare a selenide compound having a desired composition. It is of course possible to vary the order in which the metal components are evaporated and the amount thereof according to a purpose.

Generally, in a thin-film solar cell of an S, Se-based chalcogenide compound semiconductor represented by Cu(In₁₋ₓ, Gaₓ)(Se,S)₂ (CIGS), an electrode layer deposited with molybdenum (Mo) metal is most widely used as a back electrode disposed between a substrate and a photoactive layer, and most of the highly-efficient solar cells have been reported to be implemented by applying Mo electrodes. However, for the purpose of tandem application or transparent solar cell implementation, it is possible to construct a solar cell using a transparent electrode layer such as a transparent conductive oxide material instead of using an opaque metal electrode.

### SUMMARY

In a thin film solar cell using an S, Se-based chalcogenide thin film represented by CIGS as a photoactive layer, when a transparent conductive oxide material other than an Mo metal electrode is used as a back electrode, a Ga oxide layer hindering carrier movement is formed between a transparent conductive oxide layer and the photoactive layer, thereby deteriorating the performance of a device, or the transparent conductive oxide material applied as the back electrode is changed and not able to function as a back electrode, thereby deteriorating the performance of the device.

Thus, the present disclosure provides an S, Se-based chalcogenide thin film solar cell using a transparent back electrode including a transparent conductive oxide, the thin film solar cell having a transparent electrode to which a chemically stable transparent conductive oxide material is applied.

The present disclosure also provides a thin film solar cell in which a chemically more stable transparent conductive oxide thin film material is placed directly under a photoactive layer as a transparent back electrode to suppress the formation of a Ga oxide layer hindering carrier movement.

The present disclosure also provides a thin film solar cell which prevents a transparent conductive oxide material applied as a back electrode from changing and thereby not being able to function as a back electrode.

However, these are only exemplary and do not limit the scope of the present invention.

In accordance with an embodiment, a thin film solar cell includes: a transparent substrate; a photoactive layer including an S, Se-based chalcogenide material; and a back electrode disposed between the transparent substrate and the photoactive layer and including a transparent conductive oxide containing titanium (Ti).

In accordance with an embodiment, the photoactive layer may be disposed directly on the back electrode.

In accordance with an embodiment, the back electrode may include: a first transparent conductive oxide layer disposed on an upper portion thereof and containing titanium (Ti); and a second transparent conductive oxide layer disposed on a lower portion thereof and at least not containing titanium (Ti).

In accordance with an embodiment, the second transparent conductive oxide layer may include at least any one of transparent conductive oxide layers composed of an In-based oxide, a Sn-based oxide, and a Zn-based oxide.

In accordance with an embodiment, the back electrode may be a transparent conductive oxide containing titanium (Ti) doped with at least any one metal impurities of Nb, Ta, or Cr.

In accordance with an embodiment, the amount of titanium (Ti) among the components of the titanium (Ti) and the metal impurities except oxygen in the back electrode may be 85% to less than 100% by atomic fraction.

In accordance with an embodiment, the resistivity of the transparent conductive oxide containing titanium (Ti) may be lower than 10 Ωcm (greater than 0).

In accordance with an embodiment, the thickness of a transparent conductive oxide thin film layer may be 1 nm to 1000 nm.

In accordance with an embodiment, the photoactive layer may be Cu(In₁₋ₓGaₓ)(Se,S)(0<x<1).

In accordance with an embodiment, the transparent conductive oxide containing titanium (Ti) may prevent a Ga oxide layer from forming between the photoactive layer and the back electrode.

In accordance with an embodiment, the first transparent conductive oxide layer may act as a protective layer for the second transparent conductive oxide layer to prevent the Ga oxide layer from forming between the photoactive layer and the first transparent conductive oxide layer.

In accordance with an embodiment, the amount of light passing through the transparent substrate to be absorbed into the photoactive layer may be relatively increased in the case in which the back electrode is composed of the first transparent conductive oxide layer and the second transparent conductive oxide layer than in the case in which the back electrode is composed only of the second transparent conductive oxide layer.

### BRIEF DESCRIPTION OF THE DRAWINGS

Embodiments can be understood in more detail from the following description taken in conjunction with the accompanying drawings, in which:

FIG. 1 shows the results before and after the heat treatment in which an ITO thin film was heat treated at 550° C. for 1 hour under a gas atmosphere containing sulfur, in accordance with a comparative example of the present invention;

FIG. 2 shows XRD results before and after the heat treatment in which a Mo back electrode thin film was heat treated at 550° C. for 1 hour under a gas atmosphere containing sulfur, in accordance with a comparative example of the present invention;

FIG. 3 shows J-V characteristics of a solar cell manufactured by synthesizing a photoactive layer on a Mo back electrode and an ITO back electrode, in accordance with a comparative example of the present invention;

FIG. 4 shows a Scanning Transmission Electron Microscope (STEM) High Angle Annular Dark Field (HAADF) image showing an interfacial structure and a Ga composition between an ITO thin film and a CIGS photoactive layer, in accordance with a comparative example of the present invention;

FIGS. 5A, 5B and 5C are schematic views showing a back electrode disposed on a transparent substrate, in accordance with a comparative example and various examples of the present invention;

FIG. 6 shows the results of measuring resistivity of a TiO₂ (TNO) thin film doped with impurities, in accordance with an embodiment of the present invention;

FIGS. 7A and 7B show the comparison of XRD results before and after the heat treatment in which a TiO₂ thin film doped with impurities and an SnO₂ thin film doped with F were respectively heat treated at 550° C. for 1 hour under a gas atmosphere containing sulfur, in accordance with a comparative example and Example 1 of the present invention;

FIG. 8 shows the comparison of J-V characteristics of a solar cell manufactured by a two-step process using a conventional ITO thin film and a TiO₂ (TNO) thin film doped with Nb impurities, in accordance with a comparative example and Example 1 of the present invention;

In FIG. 9, compared are the interfacial structures and Ga composition distributions obtained by using Scanning Transmission Electron Microscope (STEM) High Angle Annular Dark Field (HAADF) at the interface area between a photoactive layer made of CGS thin film formed by an evaporation method and a transparent back electrode made of either a conventional transparent oxide of ITO film or a 10 nm thick TiO₂(TNO) layer doped with impurity formed on the conventional ITO thin film, in accordance with Example 2 of the present invention;

FIG. 10 compares the compositional line profiles extracted from the High Angle Annular Dark Field (HAADF) images obtained at the interface area between a photoactive layer made of CGS thin film formed by an evaporation method and a transparent back electrode made of either a conventional transparent oxide of ITO film or a 10 nm thick TiO₂(TNO) layer doped with impurity formed on the conventional ITO thin film, in accordance with Example 2 of the present invention, in accordance with Example 2 of the present invention;

FIGS. 11A and 11B show reflection spectra of solar cells, which were measured from the back side of the glass substrate, for various thicknesses of TiO₂(TNO) protective layer doped with impurities formed on ITO films with thicknesses of 200 nm and 500 nm, respectively, in accordance with Example 2 of the present invention. FIG. 11C shows the corresponding variation in color coordinates obtained from the reflection spectra shown in FIGS. 11A and 11B; and

FIGS. 12A and 12B show the change in the reflected photocurrents due to change in reflection spectra, and the corresponding change in absorbed photocurrent in a photoactive layer, in accordance with an embodiment of the present invention.

### DETAILED DESCRIPTION OF EMBODIMENTS

The following detailed description of the present invention refers to the accompanying drawings, which illustrate, by way of example, specific embodiments in which the present invention may be practiced. These embodiments are described in sufficient detail to enable those skilled in the art to practice the present invention. It is to be understood that the various embodiments of the present invention are different from each other, but are not necessarily mutually exclusive. For example, specific features, structures, and characteristics described herein may be implemented in other embodiments without departing from the spirit and scope of the present invention in connection with one embodiment. It is also to be understood that the position or arrangement of individual components in each disclosed embodiment may be varied without departing from the spirit and scope of the present invention. Accordingly, the following detailed description is not intended to be taken in a limiting sense, and the scope of the present invention is to be limited only by the appended claims, along with all ranges equivalent to those claimed in the claims, if properly described. In the drawings, like reference numerals refer to the same or similar functions throughout various aspects, and the length, area, thickness, shape, and the like may be exaggerated for convenience.

Hereinafter, preferred embodiments of the present invention will be described in detail with reference to the accompanying drawings, so that those skilled in the art can easily carry out the present invention.

The most widely used materials for a transparent electrode are metal oxides. Typical examples of a transparent conductive oxide (TCO) material include binary oxides such as indium oxide (In₂O₃), tin oxide (SnO₂), zinc oxide (ZnO), cadmium oxide (CdO), and titanium oxide which are doped with impurities. In addition to these, there are various kinds using various oxide combinations such as a mixture of zinc oxide and tin oxide (ZnO—SnO₂) and a mixture of indium oxide and zinc oxide (In₂O₃—ZnO). Among these, the most widely used oxide due to low resistivity and excellent light transmittance thereof is In₂O₃ (ITO: indium tin oxide) which is doped with Sn. In addition, a tin oxide-based material in which SnO₂ is doped with impurities such as F (FTO) or Sb (ATO), and recently, a zinc oxide-based material in which ZnO is doped with impurities such as Al (AZO), Ga (GZO), or B (BZO) have been widely used.

Such transparent conductive oxides are known to be relatively stable at room temperature. However, it is well known that when heated to a high temperature, the transparent conductive oxides become chemically unstable although there are differences according to the kind of oxides, atmosphere and temperature. As described above, the formation of a Ga oxide layer hindering carrier movement between an ITO transparent conductive oxide layer and a photoactive layer in an evaporation method means that oxygen which is the source of oxidation of Ga, a constituent element of the photoactive layer, is provided by ITO. That is, a portion of the oxygen constituting the ITO is discharged from the ITO and combined with the Ga which is a constituent element of the photoactive layer. In addition, when the photoactive layer is manufactured by the two-step process under a gas atmosphere containing sulfur, oxygen in an ITO thin film is replaced by sulfur having a high chemical potential to be changed into a sulfide form.

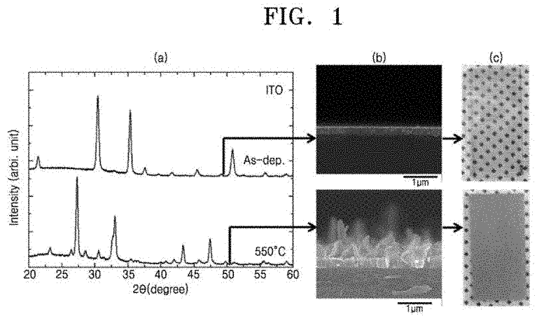

FIG. 1 shows the results before and after the heat treatment in which an ITO thin film was heat treated at 550° C. for 1 hour under a gas atmosphere containing sulfur, in accordance with a comparative example of the present invention.

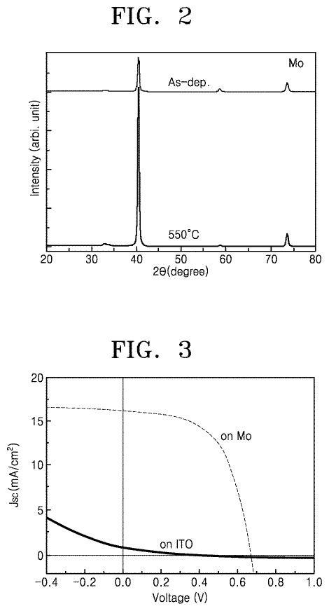

FIG. 2 shows XRD results before and after the heat treatment in which a Mo back electrode thin film was heat treated at 550° C. for 1 hour under a gas atmosphere containing sulfur, in accordance with a comparative example of the present invention.

FIG. 3 shows J-V characteristics of a solar cell manufactured by synthesizing a photoactive layer on a Mo back electrode and an ITO back electrode, in accordance with a comparative example of the present invention.

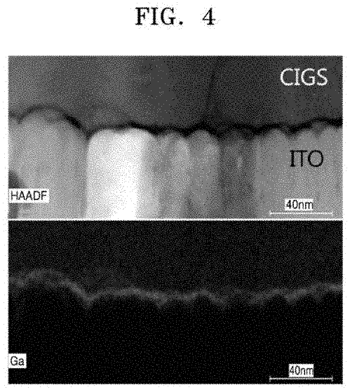

FIG. 4 shows a Scanning Transmission Electron Microscope (STEM) High Angle Annular Dark Field (HAADF) image showing an interfacial structure and a Ga composition between an ITO thin film and a CIGS photoactive layer, in accordance with a comparative example of the present invention.

First, (c) of FIG. 1 is a photograph of a glass substrate visible to the naked eye, and it can be confirmed that the glass substrate was transparent before heat treatment, but was changed to have a yellowish appearance which is not transparent after the heat treatment.

(a) of FIG. 1 shows the results of XRD measurement before and after the heat treatment, and it can be seen that diffraction peaks observed in a specimen after the heat treatment are significantly different from those of ITO thin film before the heat treatment. In addition, the sheet resistance of the ITO thin film before the heat treatment was 6 Ω/sq. However, the sheet resistance of the ITO thin film after the heat treatment was increased to 5×10⁵ Ω/sq by about 55,000 times. Thus, it was confirmed that the ITO thin film could no longer serve as an electrode.

(b) of FIG. 1 is an SEM image from which it can be confirmed that the ITO thin film had a smooth surface before the heat treatment, but the surface thereof was changed to have a rough structure after the heat treatment. In addition, between the ITO thin film and a CIGS interface, there exists a region of a few nanometers having high concentration of Ga. Such region is a Ga oxide which becomes a factor to hinder carrier movement due to high resistance thereof.

Table 1 below shows the comparison of efficiency of thin film solar cells manufactured by a two-step process in which photoactive layers of Cu, In and Ga were deposited on either Mo or ITO back electrode, and annealed under a hydrogen sulfide (H₂S) gas atmosphere.

TABLE 1

| Back electrode | Efficiency (%) | V_{oc} (V) | J_{sc} (mA/cm²) | FF (%) |
|---|---|---|---|---|
| Mo | 5.2 | 0.663 | 14.1 | 56.0 |
| ITO | 0.5 | 0.524 | 3.3 | 28.9 |

As shown in the table, it was possible to obtain a solar cell having a certain degree of efficiency on the Mo back electrode layer. However, it was not possible to obtain a meaningful efficiency when the ITO thin film was used as the back electrode. From this comparison, it can be known that the difference in performance of the solar cells were caused by the difference in back electrode materials since two specimens were made in the same batch by the same process in which the same photoactive layer, upper buffer layer, and upper transparent electrode layer were disposed except that the two specimens had different back electrodes, one of Mo and the other of ITO.

In addition, unlike ITO, the Mo thin film is stable during the heat treatment in a sulfide gas atmosphere at a high temperature. From this result, it can be known that when synthesizing a CIGS photoactive layer by heat treatment in a sulfide gas atmosphere or a sulfur atmosphere using the two-step process method, a transparent conductive oxide thin film represented by ITO is problematic.

There is no problem when depositing CIGS on a Mo layer, which is a commonly used back electrode, by using the evaporation method. However, when a transparent oxide back electrode is used, problems occur. As shown in FIG. 3, when a CIGS thin film is formed as a photoactive layer on the ITO thin film, a strong reverse diode hindering carrier movement is formed on the surface of the back electrode. Such reverse diode is known to be caused by an oxide of gallium (Ga) formed at an interface between ITO and CIGS.

As observed in the above results, it can be known that problems may occur when an S, Se-based chalcogenide photoactive layer represented by CIGS is fabricated on a back electrode made up of transparent conductive oxide instead of a metal back electrode such as Mo by using both the two-step process method and the evaporation method.

The present invention has been made based on the above observations in order to suppress the formation of a Ga oxide layer hindering carrier movement by applying a stable transparent conductive oxide in a process of synthesizing an S, Se-based chalcogenide photoactive layer represented by CIGS, or to prevent a transparent conductive oxide material applied as a back electrode from changing and thereby not being able to function properly as the back electrode.

In accordance with an embodiment of the present invention, provided is a thin film solar cell including a transparent substrate (10), a photoactive layer (30) including an S, Se-based chalcogenide material, and a back electrode (20) disposed between the transparent substrate (10) and the photoactive layer (30) and including a transparent conductive oxide containing titanium (Ti).

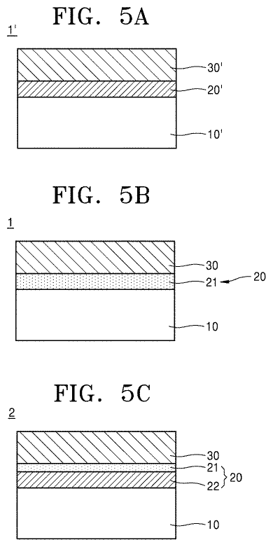

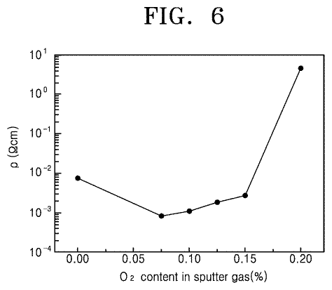

FIG. 5A is a schematic view showing a back electrode disposed on a transparent substrate, in accordance with a comparative example of the present invention. FIGS. 5B and 5C show schematic views showing a back electrode disposed on a transparent substrate, in accordance with various examples of the present invention.

Referring to FIGS. 5A, 5B and 5C, a thin film solar cell may include the transparent substrate (10), the back electrode (20), and the photoactive layer (30).

The transparent substrate (10) is made of a transparent material and may be glass. However, the present invention is not limited thereto. For example, a substrate made of a material having high light transmittance such as plastic or polymer may be used other than glass.

The back electrode (20) includes a transparent conductive oxide and may be formed on the transparent substrate (10).

First, as shown in FIG. 5A, a thin film solar cell (1′) in accordance with a comparative example has a transparent conductive oxide layer (20′) composed of a conventional In-based oxide, Sn-based oxide or Zn-based oxide on a transparent substrate (10′).

Next, as shown in FIG. 5B, a thin film solar cell (1) in accordance with Example 1 is characterized by using the back electrode (20) including a transparent conductive oxide layer (21) which is an oxide having titanium (Ti) as the main component. That is, in FIG. 5B, the transparent conductive oxide layer (20′) composed of the conventional In-based oxide, Sn-based oxide or Zn-based oxide is not included.

In accordance with an embodiment, the back electrode (20) may be a transparent conductive oxide including titanium (Ti) doped with at least any one metal impurities of Nb, Ta, or Cr. At this time, the amount of titanium (Ti) among the components of the titanium (Ti) and the metal impurities except oxygen in the back electrode may be 85% to less than 100% by atomic fraction.

Next, as shown in FIG. 5C, a thin film solar cell (2) in accordance with Example 2 is characterized by using the back electrode (20) in which the transparent conductive oxide layer (21), which is an oxide having titanium (Ti) as the main component, is formed on a transparent conductive oxide layer (22) composed of the conventional In-based oxide, Sn-based oxide or Zn-based oxide.

In other words, the back electrode (20) may include a first transparent conductive oxide layer (21) disposed on an upper portion thereof and containing titanium (Ti) and a second transparent conductive oxide layer (22) disposed on a lower portion thereof and at least not containing titanium (Ti). The second transparent conductive oxide layer (22) may include at least any one of transparent conductive oxide layers composed of an In-based oxide, a Sn-based oxide, or a Zn-based oxide. The transparent conductive oxide layer (21), which is an oxide having titanium (Ti) as the main component, may be used as a protective layer. The existing transparent conductive oxide layer (22) of the FIG. 5(C) does not necessarily have to be a transparent conductive oxide. That is, the existing transparent conductive oxide layer (22) may be a transparent conductive electrode in which a metal nanowire, a carbon nanotube, a graphene, and the like, which are commonly studied or developed, are dispersed or mixed, or a transparent conductive electrode having a multilayer structure of oxide/metal/oxide and the like.

In addition, in accordance with an embodiment of the present invention, the resistivity of the transparent conductive oxide (21) containing titanium (Ti) may be lower than 10 Ωcm (greater than 0).

FIG. 6 shows the results of measuring resistivity of a TiO₂ (TNO) thin film doped with impurities, in accordance with an embodiment of the present invention.

Referring to FIG. 6, the resistivity changes depending on the amount of oxygen in sputter gas, and when the concentration of oxygen is 0.2% or less, it can be known that resistivity having a resistivity value lower than 10 Ωcm, which is thought to be a value sufficient for serving as a transparent electrode to some extent, is obtained.

In addition, in accordance with an embodiment of the present invention, the thickness of the transparent conductive oxide layer (21) containing titanium (Ti) may be 1 nm to 1000 nm.

The photoactive layer (30) may be disposed on the back electrode (20). The photoactive layer (30) may use an S, Se-based chalcogenide compound semiconductor. For example, the photoactive layer (30) may use an S, Se-based chalcogenide compound semiconductor represented by CIGS, and the photoactive layer (30) may be Cu(In₁₋ₓ, Gaₓ)(Se,S)₂(O<x<1).

In accordance with an embodiment of the present invention, the photoactive layer (30) may be disposed directly on the back electrode (20). Thus, by placing the back electrode (20) directly under the photoactive layer (30), it is possible to suppress the formation of a Ga oxide layer hindering carrier movement.

On the photoactive layer (30), a buffer layer (not shown), an upper electrode (not shown) and the like may be further disposed.

Hereinafter, embodiments to promote understanding of the present invention will be described. However, it should be understood that the following examples are provided only to promote understanding of the present invention, and the present invention is not limited to the following examples.

### EXAMPLES AND COMPARATIVE EXAMPLES

### Example 1

A transparent conductive oxide which is an oxide having titanium (Ti) as the main component, provided by the present invention, specifically, a TiO₂ (TNO) thin film doped with Nb was prepared. Thereafter, a solar cell having a Cu—In—Ga—S thin film as a photoactive layer was manufactured, the Cu—In—Ga—S thin film formed by the two-step process method on the TiO₂ (TNO) thin film doped with Nb.

### Example 2

On a conventional ITO thin film, a TiO₂ (TNO) thin film doped with Nb was formed to a thickness of 10 nm, and then by using the evaporation method, a CIGS photoactive layer thin film was prepared.

### Comparative Example 1

A solar cell having a Cu—In—Ga—S thin film as a photoactive layer was manufactured by the two-step process method. On an ITO thin film, which is a conventional transparent conductive oxide, metallic Cu, In and Ga layers were deposited by using the evaporation method. Thereafter, metallic Cu, In and Ga layers were transformed into (a solar cell having) a Cu—In—Ga—S(thin film as a) photoactive layer by heat treatment in hydrogen sulfide (H₂S) gas atmosphere.

### Comparative Example 2

A SnO₂ (FTO) thin film doped with F, which is one of conventional transparent conductive oxides, was prepared.

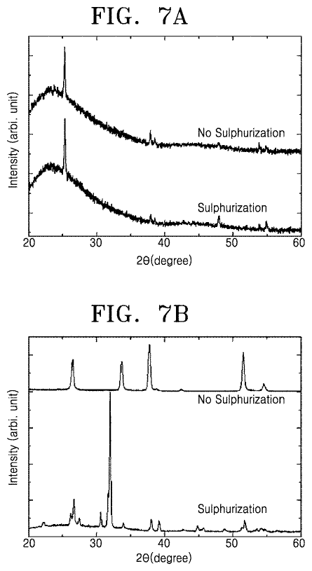

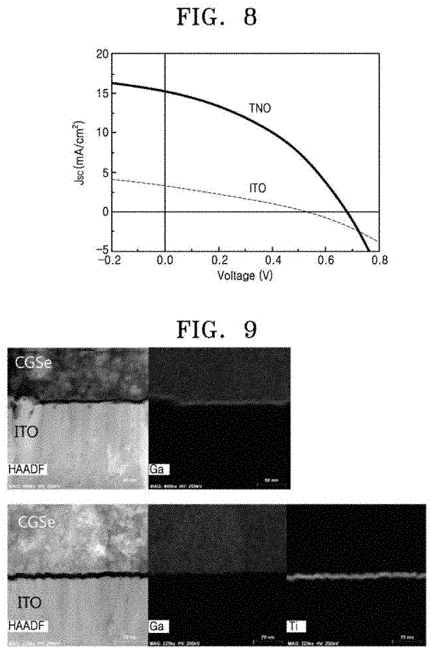

FIGS. 7A and 7B show the comparison of XRD results before and after the heat treatment in which a TiO₂ thin film doped with impurities and a SnO₂ thin film doped with F were respectively heat treated at 550° C. for 1 hour under a gas atmosphere containing sulfur, in accordance with a comparative example and Example 1 of the present invention.

The instability of the ITO thin film, which is the most widely used transparent conductive oxide, is already shown in FIG. 1. SnO₂-based transparent conductive oxide thin films are known to be stable as compared with In₂O₃-based thin films. However, as it can be confirmed in FIG. 7B, when heat treatment is performed in a hydrogen sulfide atmosphere at a high temperature, crystal peaks exhibiting the crystallinity of sulfide appears due to the influence of sulfur.

However, as it can be seen from FIG. 7A, the TiO₂ (TNO) thin film doped with Nb shows exactly the same XRD peaks of TiO₂ for both the as-deposited and the heat-treated specimens in the hydrogen sulfide gas atmosphere.

In addition, in the case of the SnO₂ thin film, the resistance before the heat treatment was 7.1 Ω/sq. However, the resistance thereof after the heat treatment was increased to 1×10⁵ sq by about 14,000 times. On the other hand, in the case of a TNO thin film, the resistance was increased from 75 Ω/sq. to 106 Ω/sq. by only about 1.4 times, thereby exhibiting stability of electrical properties as well as structural stability.

From such results, it can be confirmed that the TiO₂-based transparent conductive oxide doped with impurities, provided by the present invention, may provide durability to withstand the sulfurization conditions used in a process of synthesizing an S, Se-based chalcogenide photoactive layer by using the two-step process method. In addition, since sulfur is more reactive than selenium (Se) at a high temperature, if the TiO₂-based transparent conductive oxide doped with impurities can withstand the sulfurization conditions, it should be apparent that the TiO₂-based transparent conductive oxide doped with impurities can more easily withstand treatment conditions for selenization.

FIG. 8 shows the comparison of J-V characteristics of a solar cell manufactured by a two-step process using a conventional ITO thin film and a TiO₂ (TNO) thin film doped with Nb impurities, in accordance with a comparative example and Example 1 of the present invention.

The solar cell manufactured on the conventional ITO thin film showed no measurable efficiency, but the solar cell composed using the TiO₂ (TNO) thin film doped with Nb impurities showed about 4% of efficiency.

In FIG. 9, compared are the interfacial structures and Ga composition distributions obtained by using Scanning Transmission Electron Microscope (STEM) High Angle Annular Dark Field (HAADF) at the interface area between a photoactive layer made of CGS thin film formed by an evaporation method and a transparent back electrode made of either a conventional transparent oxide of ITO film or a 10 nm-thick TiO₂(TNO) layer doped with impurity formed on the conventional ITO thin film, in accordance with Example 2 of the present invention.

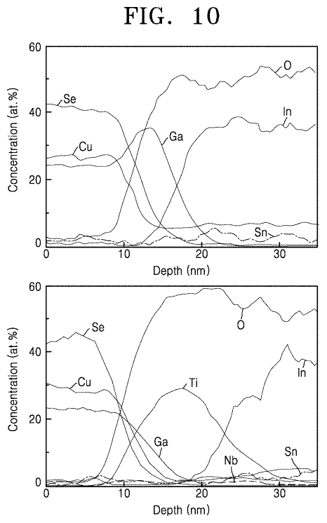

FIG. 10 compares the compositional line profiles extracted from the High Angle Annular Dark Field (HAADF) images obtained at the interface area between a photoactive layer made of CGS thin film formed by an evaporation method and a transparent back electrode made of either a conventional transparent oxide of ITO film or a 10 nm-thick TiO₂(TNO) layer doped with impurity formed on the conventional ITO thin film, in accordance with Example 2 of the present invention, in accordance with Example 2 of the present invention. As it can be confirmed in FIG. 9 and FIG. 10, when a CIGS layer is formed on the ITO thin film by the evaporation method, it can be seen that a Ga-enriched layer having a thickness of a few nanometers is present at an interface. However, in a specimen in which the ITO thin film is covered with the TNO thin film, it can be seen that the Ga-enriched layer is not present at all. From such results, it can be seen that by simply covering the existing transparent conductive oxide layer with the TiO₂ thin film doped with impurities in the form of a thin layer (that is, applied as a protective layer) instead of substituting the entire transparent conductive back electrode with the same, it is possible to effectively suppress the formation of a Ga oxide layer hindering carrier movement at the interface.

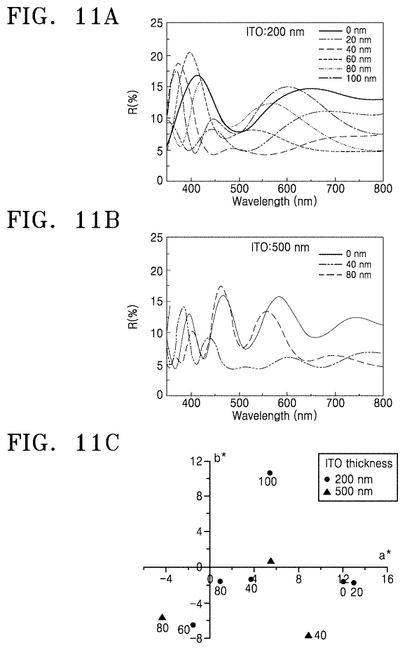

FIGS. 11A and 11B show reflection spectra of solar cells, which were measured from the back side of the glass substrate, for various thicknesses of TiO₂(TNO) protective layer doped with impurities formed on ITO films with thicknesses of 200 nm and 500 nm, respectively, in accordance with Example 2 of the present invention. FIG. 11C shows the according variation in color coordinates obtained from the reflection spectra shown in FIGS. 11A and 11B.

From FIGS. 11A and 11B, it can be confirmed a completely different reflection spectrum appeared depending on the thickness of the protective layer. Since ITO and the TiO₂ (TNO) thin film doped with impurities of the protective layer have different refractive indexes, various spectra are shown by a combination of thicknesses.

FIG. 11C shows color coordinates obtained from each spectrum, and as a color coordinate system, CIE L*a*b* coordinate system defined based on the antagonistic color theory of human was used. An L* value indicates brightness. When the L* value is 0, it indicates the black color and when the L* value is 100, it indicates the white color. In addition, an a* value indicates a degree of redness or greenness. When the a* value is a negative number, it indicates a green-oriented color and when the a* value is a positive number, it indicates a red-oriented or a purple-oriented color. A b* value indicates a degree of yellowness or blueness. When the b* value is a negative number, it indicates a blue-oriented color and when the b* value is a positive number, it indicates a yellow-oriented color.

Such results reveal (show) that when the thickness of a transparent conductive oxide protective layer doped with impurities is varied while using a conventional transparent conductive oxide material as it is, a rear surface reflection of various colors may be obtained. In addition, when a thin film solar cell having an S, Se-based chalcogenide photoactive layer is applied to an architectural BIPV window, the thin film solar cell provides an advantage of being able to control the aesthetic feel of colors which are seen from inside. In addition, the L* value was less than 43 in all thin films, and as it can be seen the reflection spectrum, since reflectivity is low, the tone of colors may change while the overall tone of the colors is dark.

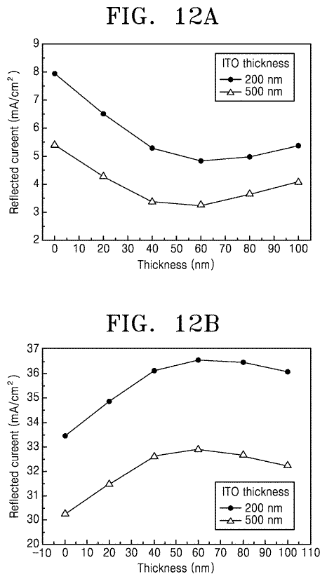

FIGS. 12A and 12B show the change in the reflected photocurrents due to change in reflection spectra, and the corresponding change in absorbed photocurrent in a photoactive layer, in accordance with an embodiment of the present invention.

From FIG. 12A, it can be seen that the amount of current which is lost by being reflected can be reduced by combining the TNO protective layer of a predetermined thickness with the underlying ITO film when compared with the case in which only the ITO thin film, a conventional transparent conductive oxide, is used. This means that there is also an effect of preventing an observer's glare by reducing reflection at a rear surface. In addition, as it can be seen from FIG. 12B, as reflectivity decreases, the amount of current generated by absorbing light into the photoactive layer is relatively increased. The result shows that a thin film solar cell using a transparent electrode on a rear surface thereof and having an S, Se-based chalcogenide photoactive layer has an advantage of improving rear surface power generation by providing an effect of increasing the amount of light entering the photoactive layer from the rear surface.

As described above, in accordance with an embodiment of the present invention, in an S, Se-based chalcogenide thin film solar cell using a transparent back electrode including a transparent conductive oxide, there is an effect of applying a transparent conductive oxide material which is chemically stable as a transparent electrode.

In addition, in accordance with an embodiment of the present invention, by placing a chemically more stable transparent conductive oxide thin film material directly under a photoactive layer as a transparent back electrode, there is an effect of suppressing the formation of a Ga oxide layer hindering carrier movement.

In addition, in accordance with an embodiment of the present invention, there is an effect preventing a transparent conductive oxide material applied as a back electrode from changing and thereby not being able to function as a back electrode.

However, the scope of the present invention is not limited by these effects.

Although the chalcogenide thin film solar cell having a transparent back electrode has been described with reference to the specific embodiments, it is not limited thereto. Therefore, it will be readily understood by those skilled in the art that various modifications and changes can be made thereto without departing from the spirit and scope of the present invention defined by the appended claims.

What is claimed is:

1. A thin film solar cell, comprising:
a transparent substrate;
a photoactive layer including an S, Se-based chalcogenide material; and
a back electrode disposed between the transparent substrate and the photoactive layer and including a transparent conductive oxide containing titanium (Ti).

2. The thin film solar cell of claim 1, wherein the photoactive layer is disposed directly on the back electrode.

3. The thin film solar cell of claim 1, wherein the back electrode comprises:
a first transparent conductive oxide layer disposed on an upper portion thereof and containing titanium (Ti); and
a second transparent conductive oxide layer disposed on a lower portion thereof and at least not containing titanium (Ti).

4. The thin film solar cell of claim 3, wherein the second transparent conductive oxide layer comprises at least any one of transparent conductive oxide layers composed of an In-based oxide, a Sn-based oxide, or a Zn-based oxide.

5. The thin film solar cell of claim 1, wherein the back electrode is a transparent conductive oxide containing titanium (Ti) doped with at least any one metal impurities of Nb, Ta, or Cr.

6. The thin film solar cell of claim 5, wherein the amount of titanium (Ti) among the components of the titanium (Ti) and the metal impurities except oxygen in the back electrode is at least 85% to less than 100% by atomic fraction.

7. The thin film solar cell of claim 1, wherein the resistivity of the transparent conductive oxide containing titanium (Ti) is lower than 10 Ωcm (greater than 0).

8. The thin film solar cell of claim 1, wherein the thickness of a transparent conductive oxide thin film layer is 1 nm to 1000 nm.

9. The thin film solar cell of claim 1, wherein the photoactive layer is Cu(In1−xGax)(Se,S) (0<x<1).

10. The thin film solar cell of claim 1, wherein the transparent conductive oxide containing titanium (Ti) prevents a Ga oxide layer from forming between the photoactive layer and the back electrode.

11. The thin film solar cell of claim 3, wherein the first transparent conductive oxide layer acts as a protective layer for the second transparent conductive oxide layer to prevent a Ga oxide layer from forming between the photoactive layer and the first transparent conductive oxide layer.

12. The thin film solar cell of claim 3, wherein the amount of light passing through the transparent substrate and then absorbed into the photoactive layer is relatively increased in a case in which the back electrode is composed of the first transparent conductive oxide layer and the second transparent conductive oxide layer than in a case in which the back electrode is composed only of the second transparent conductive oxide layer.
